(19) United States
(12) Patent Application Publication
(10) Pub. No.: US 2025/0148170 A1
(43) Pub. Date: May 8, 2025

(54) Systems and Methods for Automatic Generation of Building Elements Graph

(71) Applicant: Procore Technologies, Inc., Carpinteria, CA (US)

(72) Inventors: Matt Man, Thornhill (CA); Mohammad Mostafa Soltani, Toronto (CA)

(21) Appl. No.: 18/501,267

(22) Filed: Nov. 3, 2023

(51) Int. Cl. G06F 30/27; G06F 30/13

(52) U.S. Cl. CPC G06F 30/27; G06F 30/13

(57) ABSTRACT

A computing platform is configured to: (i) train a machine-learning model by carrying out a machine learning process on a training data set that includes that includes construction-based data objects including indications of a plurality of building elements and indications of respective logical relationships between pairs of the building elements, (ii) receive a request to generate a building elements graph for a given construction project, (iii) input construction project data associated with the given construction project into the machine-learning model, thereby (a) identifying building elements of the given construction project, (b) determining a set of respective physical relationships between pairs of the building elements and a given set of respective logical relationships between pairs of the building elements, and (c) based on the given set of respective physical relationships and the given set of respective logical relationships, generating a building elements graph for the given construction project.

### BACKGROUND

Construction projects are often complex endeavors involving the coordination of many professionals across several discrete phases. Such projects have multiple planning and building phases that occur and require lengthy communication. The planning phases may involve contract bidding, contractor selection, project feasibility studies, regulatory approval and/or permitting, among other known planning phases.

Typically, a construction project commences with a design phase, where architects design the overall shape and layout of a construction project, such as a building. Next, engineers engage in a planning phase where they take the architects' designs and produce engineering drawings and plans for the construction of the project. At this time, engineers may also design various portions of the project's infrastructure, such as HVAC, plumbing, electrical, etc., and produce plans reflecting these designs as well.

After, or perhaps in conjunction with, the planning phase, contractors may engage in a logistics phase to review these plans and begin to allocate various resources to the project, including determining what materials to purchase, scheduling delivery, and developing a plan for carrying out the actual construction of the project. Finally, during the construction or implementation phase, construction professionals begin to construct the project based on the latest available designed or construction ready plans.

Such construction planning, design, and implementation may involve massive amounts of events and information that requires documentation and accurate reporting. Software technology has been developed to enable electronic management of information associated with a construction project.

### Overview

As mentioned above, software technology has been developed to enable computing platforms to ingest and store information associated with construction projects, to facilitate electronic management of construction projects and associated information and data. Particularly, mapping and/or graphing software has been utilized in detailing structure and elements of a building and/or project, for organization and/or management purposes.

As defined herein, a “construction project” refers to any development, construction, demolition, and/or removal of improvements to an existing space, public or private infrastructure, landscaping, greenery, and the like. A “construction project task” refers to one or more sub-divided tasks associated with a construction project, which may be one of a planning task, an engineering task, a task to redo something that was done (a rework task), and/or a construction task, among other possibilities. Said “construction projects” and/or “construction project tasks” thereof may be performed for the purposes of constructing, destructing, and/or otherwise modifying any of various building elements as part of an overall built environment.

To that end, a “building element,” as defined herein, refers, generally to any component of a construction project that is constructed, built, installed, demolished, and/or otherwise modified over the course of a construction project. In this regard, a building element may refer, generally, to any sub-divided part or component of the construction project, which vary, greatly, in scope and/or type based on the type of construction project. For example, some building elements may be relatively large in size or scope (e.g., a floor of a building, an underground storage tank, a roof of a building, etc.), while others may be relatively small in terms of size and scope (e.g. a piece of trim, a doorknob, a control interface for a solar panel, a thermostat, etc.). Further, some building elements may be composite elements that are formed from a collection of other building elements. For instance, an interior wall may be formed from a collection of drywall panels attached to framing that includes timber studs. Other examples are also possible.

Within a construction project, the building elements may have some relationship to one or more other building elements of the construction project thereof. Such relationships may be physical or logical, in nature. In this regard a physical relationship between building elements refers to a relationship that is based on some physical association or physical connection between building elements, such as a physical proximity and/or some location-based characteristic that is shared by two or more building elements. To that end, in many instances, physical relationships between building elements may be hierarchical in nature (e.g., a doorknob has a physical relationship with a door via attachment of the doorknob to the door, the door has a physical relationship with a door frame via attachment of the door to the door frame, the door frame has a connection to a wall by virtue of its inclusion in the wall, the wall has a physical relationship with another wall by virtue of their abutment, both walls have a physical relationship with a floor by virtue of their attachment to the floor, etc.).

Accordingly, during or after construction projects, graphing or mapping of building elements and/or respective physical relationships between such building elements, particularly on a hierarchical level, is often useful. As defined herein, a “building elements graph,” refers to any data structure that represents a plurality of building elements and one or more indications of relationships between two or more building elements. A building elements graph need not be a visual, graphic representation of such building elements and/or indication(s) of relationship therebetween, but may exist as a data structure that can be searched, queried, etc. However, it is often useful to generate a graphic representation of a building elements graph, for use either during or after a construction project.

To date, computer-based services for aiding in planning and execution aspects of a construction project, such as those developed and maintained by Procore Technologies, may be of assistance to parties interested in hierarchical descriptions of the building elements in a construction project. Such a hierarchical breakdown may be useful both during the construction phase of said project as well as during the ongoing maintenance of the resulting facilities, post-construction. For example, Procore Technologies has developed techniques for generating a location-based hierarchy that details and/or breaks down locations and associated elements, such as those discussed in U.S. patent application Ser. No. 17/957,501, entitled “Computer Systems and Methods for Identifying Location Entities and Generating a Location Entity Data Taxonomy,” which is assigned to the assignee of the present application and incorporated fully herein by reference. Further still, Procore Technologies has developed techniques for generating a construction knowledge graph that connects data objects on a construction project based on location and/or a location-hierarchy thereof, such as those discussed in U.S. patent application Ser. No. 17/307,869, published as U.S. Pat. Pub. No. 2022/0358259 and entitled “Construction Knowledge Graph,” which is assigned to the assignee of the present application and incorporated fully herein by reference.

However, currently known systems and methods for generating building elements graphs, while useful for identifying and illustrating physical relationships, may lack an indication of the aforementioned logical relationships that may exist between one or more building elements. A logical relationship refers to a relationship between two building elements that involves a functional or control-based connection between the two elements. Importantly, two building elements that are logically related may or may not have a physical relationship therebetween. For example, an HVAC unit in a first room may have a logical relationship with a thermostat that resides within a second room, because the thermostat is connected to the HVAC unit for the logical purpose of controlling the HVAC system. In such an example, HVAC unit and the thermostat may be physically distant from one another, and thus do not have a location-based or proximity-based physical relationship.

Accordingly, a building elements graph that details physical relationships and/or an associated location hierarchy or location-based graphs may lack useful information associated with logical relationships between building elements. However, it is important for various parties to a construction project to know and/or understand the logical relationships and/or associated hierarchies between building elements. Said knowledge of logical relationships between building elements could, for example, streamline troubleshooting of conflicts and other problems during construction projects, facilitate more accurate estimates of the impact of design changes, among other possibilities.

Consider, for example, a construction project for an office building, wherein the office building includes five heating/cooling zones (Zone A, Zone B, Zone C, Zone D, Zone E), with each zone including multiple different rooms. Further, the office building includes five HVAC units (HVAC A, HVAC B, HVAC C, HVAC D, and HVAC E), each associated with one of the respective zones and having a control-based logical relationship with one of five respective thermostats (thermostat A, thermostat B, thermostat C, thermostat D, thermostat E), each thermostat physically located in one of the rooms in its corresponding zone. During testing of the HVAC system, an inspector notices that there is little or no HVAC activity (e.g., air ingress, air flow, air egress, heating, air conditioning, cooling, etc.) happening in one of the rooms in Zone C. However, neither the HVAC C nor the thermostat C are physically located in the room where the inspector identified the issue, nor are they in the same room with each other. If the inspector has a building elements graph that includes both physical and logical relationships, he/she/they may first use the graph to determine the logical relationship between Zone C and HVAC C, and then determine the physical location of the HVAC C, to then inspect HVAC C for malfunction or error.

If the inspector then determines that HVAC C is in working order, he/she/they may then utilize the building elements graph to determine if there are any other operational elements associated with HVAC C. The building elements graph will indicate to the inspector that HVAC C has a functional, logical relationship with thermostat C. Now, the inspector may wish to inspect the thermostat C for any error. Again, the building elements graph, which combines indications of both physical and logical relationships, may now be useful in determining the physical location of the thermostat C. While the aforementioned example refers to the usefulness of such a building elements graph during a construction project task (e.g., an inspection) it is certainly contemplated that such building elements graphs may be useful for facilities management, maintenance, and/or upkeep after completion of the construction project.

Accordingly, a building elements graph as discussed herein may have substantial utility in aiding many parties involved with construction project and/or maintenance or upkeep of the resulting facility after construction is complete. However, obtaining the data and/or information from which logical relationships between building elements are indicated and/or derived, is often difficult and/or time consuming—even moreso than deriving location-based and/or physical relationships between building elements. Traditionally, one who is attempting to determine such logical relationships may need to look up product manuals, refer to or research different construction drawings from various different trades on the project (many of which might have been completed years ago), may require experience with or knowledge of specific building elements and functions thereof (e.g. mechanical systems, electrical connections, fluid connections, etc.), among other varied sources of information from which logical relationships may be determined. Further still, such information may all be held by different parties and hard to access by the party who is trying to determine the logical relationships. To that end, said information silos between different parties may make determination of logical relationships particularly difficult and, thus, restrict one party from seeing the broader picture of the logical relationships between the building elements in a construction project.

In some example systems for providing building elements graphs, building information modelling (BIM) may be useful in indicating, determining, and/or deriving relationships between building elements. BIM files are 3D models of a construction project that are typically embodied in a computerized form, with 3D meshes visually representing the physical elements of the construction project (e.g., walls, ducts, ceilings, pipes, conduits, etc.). The BIM file can include a vast amount of data describing the individual physical elements of the construction project and the relationships between these individual physical elements, including, for instance, the relative position, size, and/or shape of each element, and an indication of where each element will reside in relation to the other elements in the construction project. Accordingly, BIM files may be useful for deriving relationship data for building elements graphs.

However, while BIM may be useful in building elements graphing, there are drawbacks to relying, primarily, on BIM for generating building elements graphs. First, while BIM can be useful in construction projects, it is not yet widely adopted by the industry, particularly in developing nations. Some estimates indicate that BIM is not even widely used on a majority of construction projects in the developed world and, thus, it is not an always-used technology that can be relied on for providing building elements graphs. Further still, even though BIM may provide a useful resource for indicating physical relationships, it may nonetheless lack and indication of some or all logical relationships between building elements in a construction project. Accordingly, alternatives to BIM for generating building elements graphs, both for ease-of-adoption by users and for completeness' sake, are desired.

To that end, new technologies for generating building elements graphs that more fully incorporate both physical and logical relationships between building elements are disclosed herein. Such technologies utilize various machine-learning and/or artificial intelligence (AI) technologies to determine a relationship model and/or relationship rules, based on various documentation (e.g., drawings, specifications, manuals, etc.) and other historical input associated with one or more construction projects and/or individual building elements thereof.

For example, a computer-based system, as disclosed herein, may utilize a trained machine-learning model to ingest data associated with a current construction project and parse information from said data to determine physical and logical relationships between building elements of the current construction project. To that end, the machine learning model may first extract the building elements from the input data associated with the current construction project. The extracted building elements and the relationships therebetween are then utilized in generating the building elements graph.

Training of said machine-learning model may be based on prior construction-based data associated with other construction projects, as well as prior construction-based data associated with a current construction project. Said data may be compiled as a training data set, upon which the computing system carries out a machine-learning process thereon to train the machine-learning model. The machine-learning process may be any supervised, unsupervised, and/or semi-supervised machine-learning process known in the art, such as, but not limited to a neural network based process, a Graph Neural Network (GNN), a Transformer Neural Network, an autoregressive machine-learning process, or combinations thereof.

Of particular use in generating building elements graphs and/or indicating relationships thereof, the specific machine-learning models and/or techniques may relate to forms of natural language processing (“NLP”). NLP, generally, refers to an interdisciplinary field of linguistics and computer science that is concerned with processing natural language datasets, such as text corpa or speech corpa, using either rule-based or probabilistic machine learning methods. The aim of NLP is to generate models that are capable of understanding the context and meaning of data that is ingested by the model, such that the NLP model can “learn” the language or contextual meaning of terms and/or language. Thus, when utilizing machine-learning models that employ NLP in generating construction activity summaries, by training the model based on historic construction project data held in the computing platform, it will “learn” the contextual nuances of the construction projects and/or the industries thereof.

While, generally, NLP is useful for generating building elements graphs, new technologies in the field of large language models (LLMs) have the potential to generate even more accurate and optimized building elements graphs. A LLM refers to a complex machine-learning model that utilizes AI accelerator hardware to process vast amounts of text data, which may be scraped from a variety of sources, such as, but not limited to, the Internet. LLMs utilize artificial neural networks comprising millions or even billions of weights, which are then used for one or more of self-supervised learning, semi-supervised learning, or combinations thereof. LLMs operate by taking an input text and repeatedly predicting the next word input by the input text; the LLM can then review the input text versus the predictions to rank its accuracy and “learn” how to “speak” in the context of the scenario of the input text. Examples of LLMs include, but are not limited to including, Generative Pre-trained Transformer (GPT) models (e.g., GPT-3, GPT-3.5, GPT-4, GPT-4V, ChatGPT), pathways language models (PaLM), Large Language Model Meta AI (LLaMA), BigScience Large Open-science Open-access Multilingual Language Model (BLOOM), Bidirectional Encoder Representations from Transformers (BERT), among other known models and/or techniques.

One particular example of a useful architecture for machine learning and/or LLM generation is the transformer model or architecture. Transformer models utilize an attention mechanism to determine key points of context within language datasets. For example, transformer models may split a language data stream into encoded tokens, which are converted to vectors via lookup in a word embedding table of the transformer model; then, each token is contextualized within the model to determine key tokens to be amplified and lesser tokens to be diminished. In other words, transformer models “transform” text into data points, which then can be compared with similar text data to determine the importance of each section of the data, for use in future predictions or generation of text.

Training and/or retraining of an LLM, as disclosed herein, may include fine-tuning an LLM based on the specific data sets associated with, for example, a construction management platform. To that end, “fine tuning,” generally refers to a process of re-training a more generic, pre-trained LLM, based on a specific dataset; said fine-tuning may allow the LLM to adapt to the specific context of an industry and/or platform. For example, training and/or re-training of the LLMs, disclosed herein, may include fine tuning the LLM based on specific, construction-based data sets. By employing such fine-tuning of an LLM, the LLM may be configured to “speak” the language of a specific industry and/or computing platform, such as the construction industry and/or a computing platform associated therewith.

Additionally, as the LLM will have been trained to understand the form and contextual meaning of various forms of data on the construction management platform, it may have capabilities for determining discrepancies in data or actions performed in the construction project, based on its learnings from the ingestion of historical construction data.

While LLMs are useful, the systems and methods disclosed herein are not limited to using LLMs as the machine-learning model and the machine-learning model may be any machine-learning model capable of processing data, such as construction-based training data, for the purposes of generating a project elements graph. Construction-based training data utilized for training the machine-learning model may include general construction project data held by a common computing platform, such that the machine-learning model can learn the language of the construction industry, for greater identification of down-the-line relationships and/or for the contextual knowledge for determining and/or extracting building elements from input data. For example, two-dimensional (2D) drawings and/or BIM files may be input as training data to determine rules and/or relationship-indicators of common building elements, which are illustrated physically in the 2D drawing and/or BIM files.

Further still, the training data may include specification documents from a plurality of past construction projects and/or product manuals for specific products that are utilized as building elements. This type of input data may be particularly useful for the machine-learning process to evaluate and determine common rules and/or guidelines for determining logical relationships between building elements. For instance, this type of input data may include information about how building elements within a given system (e.g., an HVAC system, a fire suppression system, an irrigation system, an electrical system, etc.) functionally interact with one another. Accordingly, this type of logical relationship may not be captured, explicitly, on a 2D drawing nor in a 3D BIM file, which generally will only include a representation of each element's physical location.

For example, during processing and evaluation of a training data set that includes the aforementioned product manuals, the machine-learning model may observe that in 98% of product manuals for HVAC systems, the manual indicates that a thermostat is utilized as a controller for said HVAC unit; thus, the machine-learning model may predict that if an HVAC unit and a thermostat are present in a building, there is most likely a control-based logical relationship between the HVAC unit and the thermostat. Accordingly, if input construction data is processed by the machine-learning model and the machine-learning model extracts an HVAC unit and a thermostat from the input construction-based data, as building elements, then the machine-learning model may determine that a logical relationship is present between the HVAC unit and the thermostat.

With the model trained, a user of the computing platform and/or the computing platform itself can provide the machine-learning model with input data for a given construction project, which may include some or all of the types of input data discussed above. In some situations, a physical-based hierarchy (e.g., a graph) of location entities for the construction project may be provided as one of the inputs. However, in examples wherein such location hierarchy graphs are not present, the machine-learning model may generate a graph or portion of a graph based on an indication of physical relationships between building elements (e.g., as shown on 2D drawings for the given construction project). The machine-learning model may, then, generate a listing and/or identify a listing of identified building elements for the construction project, based on an evaluation of the input construction data. Then, the machine-learning model will determine physical and logical relationships between the extracted elements, in the form of a building element graph (e.g., a graph data structure with nodes and edges, wherein the edges signify what type of relationship exists). Optionally, a visual representation of the building elements graph may be generated for a user.

By utilizing the systems and methods disclosed herein for generating building elements graphs, efficiency and/or resource use for a construction project may be improved. For example, utilizing a platform-level system for generating building elements graphs may be a useful alternative to BIM, for projects where BIM is not available. Further still, as discussed above, even when BIM is available, BIM may not provide the insight to generate the logical relationships that are derived by the systems and methods disclosed herein and, thus, the resultant generated building elements graphs may have advantages over BIM. Further still, as indicated by some examples discussed above, the building elements graph may be used as, or in conjunction with, a streamlined inspection or repair tool for issue resolution, both during and after construction, as hierarchical information is given on both the physical and logical level, resulting in quicker identification of pain points in a construction project.

In some examples, building elements of a building elements graph may be linked to or associated with a cost or cost code for each building element, which may be derived from the input data for the given construction project (e.g., in a bill of materials or budget for the construction project). By associating this information with a building elements graph, costs associated with certain actions (e.g., repairs, replacements, etc.) may be predicted, considering both physical and logical impacts between building elements.

Still further, although the examples herein refer to the user of a building elements graph as a tool for use during the construction phase of a construction project, it is certainly contemplated that the building elements graph and/or data thereof may be utilized for and/or used to generate a facility management tool once the construction project is complete. Such a tool might take the form of a building information summary that includes a visual representation of the building elements graph, which can be utilized for providing information to a party, either during or after construction.

For example, upon completion of the construction project, the building elements graph may be stored by the computing platform and utilized to generate a facility management tool, such that an owner or operator associated with the building can utilize the building elements graph to maintain and/or manage the building. Thus, the building elements graph may leverage construction management data to generate another product for use in an alternative market, such as facility management.

To that end, in some examples wherein the building elements graph is utilized as a facilities management tool, the facilities management tool may be provided to the facility manager, via the computing platform, as an editable interface. Thus, the facility manager would be capable of updating the building elements graph, based on additions, repairs, and/or any other modifications or changes to the property. Accordingly, said alterations to the building elements graph may be stored by the computing platform and may persist or “live” with the building elements graph, regardless of whether or not the initial or current owner maintains ownership of the facility. Accordingly, the building elements graph, in such examples, may exist as a living status report, health report, and/or summary of all building elements of the building, which may be accessible to a number of parties.

For example, an owner of a building may wish to hire a contractor for a remodel of an aspect of a building; the owner may then provide the living building elements graph to the contractor, from which he/she/they can observe the specifics of the building and utilize said specifics in providing a quote for the remodel. In another example, a home insurer may be provided with the living building elements graph and utilize data therein in determining a price quote for a premium for home insurance for said property, wherein the most up to date data for the home is provided in determining said quote. Other uses of a living building elements graph, for both construction and non-construction-based parties, are certainly contemplated.

In line with the discussion above, the disclosed technology may be implemented as one or more software applications that facilitate the creation and management of data during the course of a construction project, some examples of which may include the types of software applications developed by Procore Technologies. Further, in practice, the computing platform in which the disclosed technology is incorporated may take the form of a software as a service (“SaaS”) application that comprises a front-end software component running on a user's client station or end-user device and a back-end software component running on a back-end computing platform that is accessible to the user client station or end-user device via a communication network such as the Internet.

In one aspect, disclosed herein is a method that involves a computing platform (i) training at least one machine-learning model by carrying out a machine-learning process on a training data set that includes a plurality of construction-based data objects, the plurality of construction-based data objects including indications of a plurality of building elements, indications of respective logical relationships between pairs of building elements in the plurality of building elements, wherein the at least one machine-learning model is configured to (a) receive, as input, construction project data associated with an input construction project, (b) based on the received construction project data, identify a plurality of building elements associated with the input construction project, (c) based on an evaluation of the one or more building elements associated with the input construction project, in view of the training data set, determine a set of respective physical relationships between pairs of building elements associated with the input construction project and a set of respective logical relationships between pairs of building elements associated with the input construction project, and (d) based on the determined set of respective physical relationships and the determined set of respective logical relationships, generate a building elements graph for the input construction project, (ii) receiving construction project data associated with a given construction project, (iii) receiving a request to generate a building elements graph for the given construction project, (iv) inputting the construction project data associated with the given construction project into the machine-learning model and thereby (a) identifying a plurality of building elements associated with the given construction project, the plurality of building elements including a first building element and a second building element, (b) determining a given set of respective physical relationships between pairs of the building elements associated with the given construction project and a given set of respective logical relationships between pairs of the building elements associated with the given construction project, the given set of respective logical relationships comprising a logical relationship between the first building element and the second building element, and (c) based on the given set of respective physical relationships and the given set of respective logical relationships, generating a building elements graph for the given construction project, and (v) storing the building elements graph for the given construction project on at least one machine-readable medium associated with the computing platform.

In another aspect, disclosed herein is a computing platform that includes a network interface, at least one processor, a non-transitory computer-readable medium, and program instructions stored on the non-transitory computer-readable medium that are executable by the at least one processor to cause the computing platform to carry out the functions disclosed herein, including but not limited to the functions of the foregoing method.

In yet another aspect, disclosed herein is a non-transitory computer-readable storage medium provisioned with software that is executable to cause a computing platform to carry out the functions disclosed herein, including but not limited to the functions of the foregoing method.

One of ordinary skill in the art will appreciate these as well as numerous other aspects in reading the following disclosure.

### BRIEF DESCRIPTION OF THE DRAWINGS

FIG. 1 depicts an example network configuration in which example embodiments may be implemented.

FIG. 2 depicts an example computing platform that may be configured to carry out one or more of the functions according to the disclosed technology.

FIG. 3 depicts a structural diagram of an example end-user device that may be configured to communicate with the example computing platform of FIG. 2 and also carry out one or more functions in accordance with the disclosed technology.

FIG. 4 depicts a flow diagram of an example process for generating a building elements graph, according to one possible implementation of the disclosed technology.

FIG. 5 depicts a schematic diagram illustrating example aspects of an example machine-learning model, utilized in conjunction with the systems and methods herein, according to one possible implementation of the disclosed technology.

FIG. 6 depicts an example visual representation of a data structure for a building elements graph, according to one possible implementation of the disclosed technology.

FIG. 7 depicts an example graphic interface utilized in generating and/or viewing a visual representation of a building elements graph, according to one possible implementation of the disclosed technology.

Features, aspects, and advantages of the presently disclosed technology may be better understood with regard to the following description, appended claims, and accompanying drawings, as listed below. The drawings are for the purpose of illustrating example embodiments, but those of ordinary skill in the art will understand that the technology disclosed herein is not limited to the arrangements and/or instrumentality shown in the drawings.

### DETAILED DESCRIPTION

The following disclosure refers to the accompanying figures and several example embodiments. One of ordinary skill in the art should understand that such references are for the purpose of explanation only and are therefore not meant to be limiting. Part or all of the disclosed systems, devices, and methods may be rearranged, combined, added to, and/or removed in a variety of manners, each of which is contemplated herein.

### I. Example Network Configuration

As one possible implementation, this software technology may include both front-end software running on one or more end-user devices that are accessible to users of the software technology and back-end software running on a back-end computing platform (sometimes referred to as a “cloud” platform or a “data” platform) that interacts with and/or drives the front-end software, and which may be operated (either directly or indirectly) by a provider of the front-end client software (e.g., Procore Technologies, Inc.). As another possible implementation, this software technology may include front-end client software that runs on end-user devices without interaction with a back-end platform (e.g., a native software application, a mobile application, etc.). The software technology disclosed herein may take other forms as well.

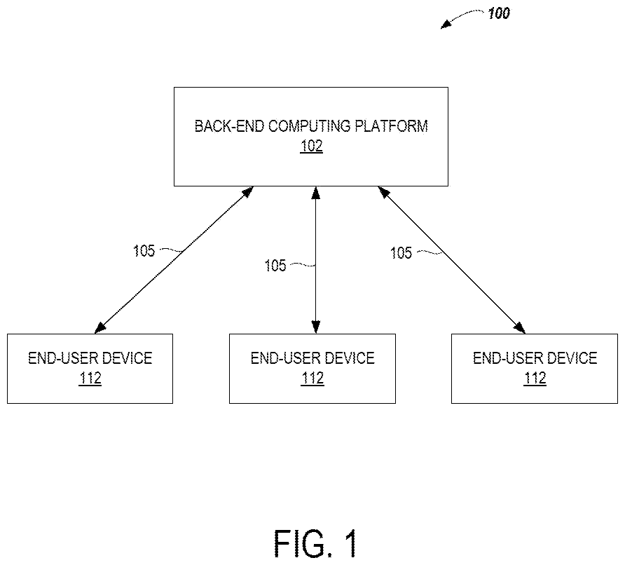

Turning now to the figures, FIG. 1 depicts an example network configuration 100 in which example embodiments of the present disclosure may be implemented. As shown in FIG. 1, the network configuration 100 includes an example back-end computing platform 102 that may be communicatively coupled to one or more client stations, depicted here, for the sake of discussion, as three end-user devices 112.

In practice, the back-end computing platform 102 may generally comprise some set of physical computing resources (e.g., processors, data storage, communication interfaces, etc.) that are utilized to implement the new software technology discussed herein. This set of physical computing resources may take any of various forms. As one possibility, the back-end computing platform 102 may comprise cloud computing resources that are supplied by a third-party provider of “on demand” cloud computing resources, such as Amazon Web Services (AWS), Amazon Lambda, Google Cloud Platform (GCP), Microsoft Azure, or the like. As another possibility, the back-end computing platform 102 may comprise “on-premises” computing resources of the organization that operates the back-end computing platform 102 (e.g., organization-owned servers).

As yet another possibility, the back-end computing platform 102 may comprise one or more dedicated servers have been provisioned with software for carrying out one or more of the computing platform functions disclosed herein, including but not limited to functions related to generating building elements graphs. The one or more computing systems of the back-end computing platform 102 may take various other forms and be arranged in various other manners as well.

In turn, end-user devices 112 may take any of various forms, examples of which may include a desktop computer, a laptop, a netbook, a tablet, a smartphone, and/or a personal digital assistant (PDA), among other possibilities.

As further depicted in FIG. 1, the back-end computing platform 102 may be configured to communicate with the end-user devices 112 over respective communication paths 105. Each communication path 105 between the back-end computing platform 102 and an end-user device 112 may generally comprise one or more communication networks and/or communications links, which may take any of various forms. For instance, each respective communication path 105 with the back-end computing platform 102 may include any one or more of point-to-point links, Personal Area Networks (PANs), Local-Area Networks (LANs), Wide-Area Networks (WANs) such as the Internet or cellular networks, cloud networks, and/or operational technology (OT) networks, among other possibilities. Further, the communication networks and/or links that make up each respective communication path 105 with the back-end computing platform 102 may be wireless, wired, or some combination thereof, and may carry data according to any of various different communication protocols. Although not shown, the respective communication paths with the back-end computing platform 102 may also include one or more intermediate systems. For example, it is possible that the back-end computing platform 102 may communicate with a given end-user device 112 via one or more intermediary systems, such as a host server (not shown). Many other configurations are also possible.

Although not shown in FIG. 1, the back-end computing platform 102 may also be configured to receive data from one or more external data sources that may be used to facilitate functions related to the processes disclosed herein. For example, the back-end computing platform 102 may be configured to generate conversation threads and facilitate conversations thereon, as discussed herein.

It should be understood that network configuration 100 is one example of a network configuration in which embodiments described herein may be implemented. Numerous other arrangements are possible and contemplated herein. For instance, other network configurations may include additional components not pictured and/or more or less of the pictured components.

### II. Example Computing Devices

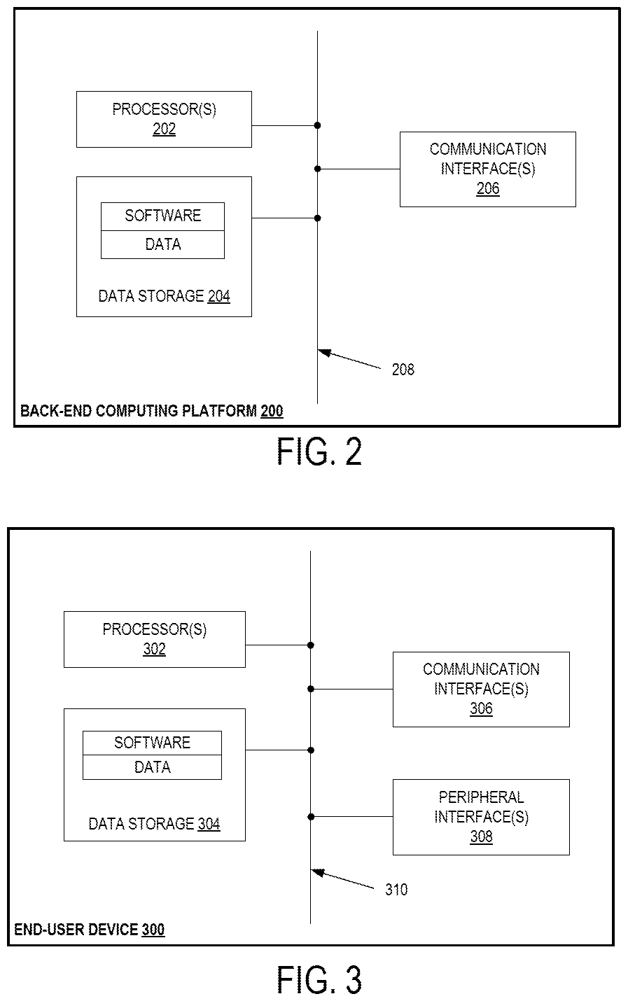

FIG. 2 is a simplified block diagram illustrating some structural components that may be included in an example computing platform 200. The example computing platform 200 could serve as, for instance, the back-end computing platform 102 of FIG. 1 that may be configured to generate building elements graphs, utilizing machine-learning models. In line with the discussion above, the computing platform 200 may generally comprise one or more computer systems (e.g., one or more servers), and these one or more computer systems may collectively include at least one or more processors 202, a data storage 204, and one or more communication interfaces 206, all of which may be communicatively linked by a communication link 208 that may take the form of a system bus, a communication network such as a public, private, or hybrid cloud, or some other connection mechanism.

The one or more processors 202 may comprise one or more processor components, such as general-purpose processors (e.g., a single- or multi-core microprocessor), special-purpose processors (e.g., an application-specific integrated circuit or digital-signal processor), programmable logic devices (e.g., a field programmable gate array), controllers (e.g., microcontrollers), and/or any other processor components now known or later developed. In line with the discussion above, it should also be understood that the one or more processors 202 could comprise processing components that are distributed across a plurality of physical computing resources connected via a network, such as a computing cluster of a public, private, or hybrid cloud.

In turn, the data storage 204 may comprise one or more non-transitory computer-readable storage mediums that are collectively configured to store (i) program instructions that are executable by the one or more processors 202 such that the computing platform 200 is configured to perform some or all of the disclosed functions and (ii) data that may be received, derived, or otherwise stored, for example, in one or more databases, file systems, or the like, by the computing platform 200 in connection with the disclosed functions. In this respect, the one or more non-transitory computer-readable storage mediums of the data storage 204 may take various forms, examples of which may include volatile storage mediums such as random-access memory, registers, cache, etc. and non-volatile storage mediums such as read-only memory, a hard-disk drive, a solid-state drive, flash memory, an optical-storage device, etc. In line with the discussion above, it should also be understood that the data storage 204 may comprise computer-readable storage mediums that are distributed across a plurality of physical computing resources connected via a network, such as a storage cluster of a public, private, or hybrid cloud. Data storage 204 may take other forms and/or store data in other manners as well.

The one or more communication interfaces 206 may be configured to facilitate wireless and/or wired communication with external data sources and/or end-user devices, such as the end-user devices 112 in FIG. 1. Additionally, in an implementation where the computing platform 200 comprises a plurality of physical computing resources connected via a network, the one or more communication interfaces 206 may be configured to facilitate wireless and/or wired communication between those physical computing resources (e.g., between computing and storage clusters in a cloud network). As such, the one or more communication interfaces 206 may take any suitable form for carrying out these functions, examples of which may include an Ethernet interface, a serial bus interface (e.g., Firewire, USB 3.0, etc.), a chipset and antenna adapted to facilitate wireless communication and/or any other interface that provides for wireless communication (e.g., Wi-Fi communication, cellular communication, short-range wireless protocols, etc.) and/or wired communication, among other possibilities. The one or more communication interfaces 206 may also include multiple communication interfaces of different types. Other configurations are possible as well.

Although not shown, the computing platform 200 may additionally include one or more interfaces that provide connectivity with external user-interface equipment (sometimes referred to as “peripherals”), such as a keyboard, a mouse or trackpad, a display screen, a touch-sensitive interface, a stylus, a virtual-reality headset, speakers, etc., which may allow for direct user interaction with the computing platform 200.

It should be understood that the computing platform 200 is one example of a computing platform that may be used with the embodiments described herein. Numerous other arrangements are possible and contemplated herein. For instance, other computing platforms may include additional components not pictured and/or more or less of the pictured components.

Turning now to FIG. 3, a simplified block diagram is provided to illustrate some structural components that may be included in an example end-user device 300, such as an end-user device 112 described above with reference to FIG. 1 and/or one or more client stations associated with the computing platform 200. As shown in FIG. 3, the end-user device 300 may include one or more processors 302, data storage 304, one or more communication interfaces 306, and one or more user-interface components 308, all of which may be communicatively linked by a communication link 310 that may take the form of a system bus or some other connection mechanism. Each of these components may take various forms.

The one or more processors 302 may comprise one or more processing components, such as general-purpose processors (e.g., a single- or a multi-core CPU), special-purpose processors (e.g., a GPU, application-specific integrated circuit, or digital-signal processor), programmable logic devices (e.g., a field programmable gate array), controllers (e.g., microcontrollers), and/or any other processor components now known or later developed.

In turn, the data storage 304 may comprise one or more non-transitory computer-readable storage mediums that are collectively configured to store (i) program instructions that are executable by the processor(s) 302 such that the end-user device 300 is configured to perform certain functions related to interacting with and accessing services provided by a computing platform, such as the example computing platform 200 described above with reference to FIG. 2, and (ii) data that may be received, derived, or otherwise stored, for example, in one or more databases, file systems, repositories, or the like, by the end-user device 300, related to interacting with and accessing the services provided by the computing platform. In this respect, the one or more non-transitory computer-readable storage mediums of the data storage 304 may take various forms, examples of which may include volatile storage mediums such as random-access memory, registers, cache, etc., and non-volatile storage mediums such as read-only memory, a hard-disk drive, a solid-state drive, flash memory, an optical-storage device etc. The data storage 304 may take other forms and/or store data in other manners as well.

The one or more communication interfaces 306 may be configured to facilitate wireless and/or wired communication with other computing devices. The one or more communication interfaces 306 may take any of various forms, examples of which may include an Ethernet interface, a serial bus interface (e.g., Firewire, USB 3.0, etc.), a chipset and antenna adapted to facilitate wireless communication, and/or any other interface that provides for any of various types of wireless communication (e.g., Wi-Fi communication, cellular communication, short-range wireless protocols, etc.) and/or wired communication. Other configurations are possible as well.

The end-user device 300 may additionally include or have interfaces for one or more user-interface components 308 that facilitate user interaction with the end-user device 300, such as a keyboard, a mouse, a trackpad, a display screen, a touch-sensitive interface, a stylus, a virtual-reality headset, and/or one or more speaker components, among other possibilities.

It should be understood that the end-user device 300 is one example of an end-user device that may be used to interact with a computing platform as described herein. Numerous other arrangements are possible and contemplated herein. For instance, in other embodiments, the end-user device 300 may include additional components not pictured and/or more or fewer of the pictured components. Further, the end user device 300 of FIG. 3 and/or the end user device 112 of FIG. 1 may be examples of client devices, utilized by users of the computing platform 200.

### III. Example Operations

As mentioned above, Procore Technologies has continued to develop software technology related to construction management and data management amongst platform users associated with such managed projects. Disclosed herein is new software technology that is generally directed to training a machine-learning model, for use with a computing platform, utilizing the trained machine-learning model to generate building elements graphs and/or associated building information summaries. As disclosed herein, an “ongoing construction project,” may refer to a construction project that is currently being monitored by one or more entities (e.g., contractors, owners, supervisors, workers, etc.). Accordingly, such ongoing construction projects may be in any phase of the construction project, such as, but not limited to, a planning phase, a design phase, a logistics phase, a construction phase, an implementation phase, a finalization phase, among other known project phases for a construction project.

i. Systems and Methods of Generating Building Elements Graphs

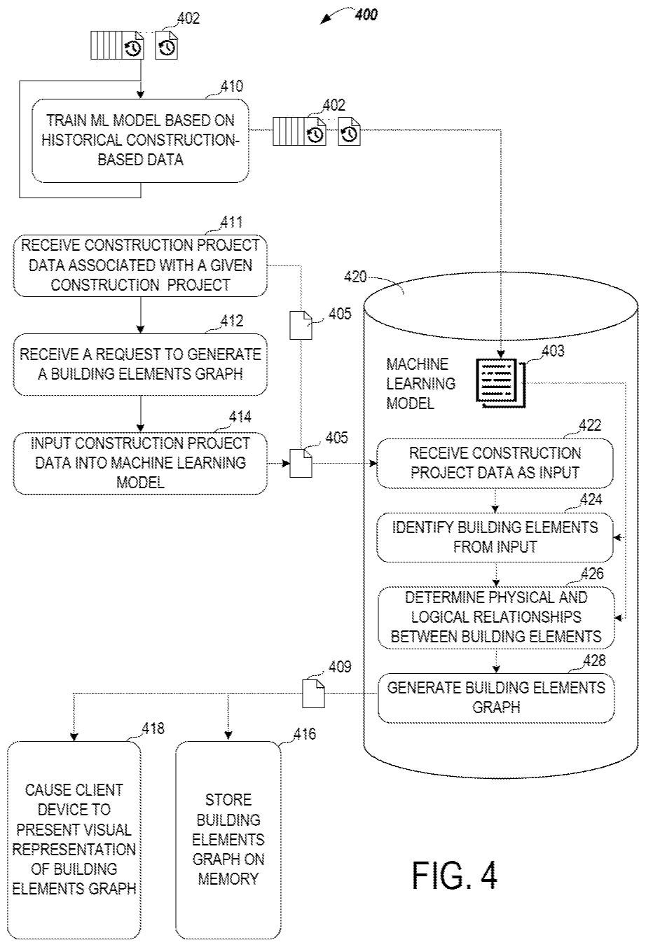

Turning now to FIG. 4, an example flow diagram is illustrated for a method 400 carried out by a computing platform, which may take the form of one or more of the back-end computing platform 102, 200, the end-user device(s) 300, or combinations thereof. The method 400 includes, at block 410, training a machine-learning model 420 by carrying out a machine-learning process on a training data set 403, which includes a plurality of construction-based data objects 402, which may be, in some examples, historical construction-based data objects and/or current project-based data objects. Each of the construction-based data objects 402 includes, at least, indications of a plurality of building elements and indications of respective logical relationships between pairs of building elements of the plurality of building elements. While the logical relationships, herein, refer to being between “pairs” of building elements, it is certainly contemplated that a logical relationship may exist between more than two building elements, such that the logical relationship exists beyond the pair.

At block 411, the method 400 includes receiving, by the computing platform 200, construction project data 405 associated with a given construction project. The receiving at block 411, by the computing platform 200, may include receiving the construction project data 405, in whole or in part, from a client device, such as an end-user device 300, receiving the construction project data 405 from memory of or associated with the computing platform 200, or combinations thereof. As will be discussed in more detail below, the construction project data 405 may be processed by the machine-learning model 420, to generate a building elements graph 409.

The construction project data 405 may include any data, datum, and/or data objects that include useful information associated with a given construction project. Examples of said useful information may include, but are not limited to including, a specification for the given construction project, drawings for the given construction project, a bill of materials (BOM) for the given construction project, user input associated with the given construction project, a location hierarchy for the given construction project, cost estimates including cost codes for various building elements, among other possibilities.

As discussed above, the construction project data 405 may include BIM data and/or BIM files associated with the given construction project. Alternatively, the construction project data 405 may not include BIM data and/or BIM files and, therefore, any output or determined physical and/or logical relationships determined by the method 400 may be determined in lieu of or as an alternative to BIM data and/or BIM files. Whether or not the construction project data 405 includes BIM data and/or BIM files, the plurality of construction-based data objects 402 on which the machine-learning model 420 is trained may include BIM data and/or BIM files. By training the machine-learning model 420 based on, at least, BIM data and/or BIM files, the machine-learning model 420 may gain insight into various known or common physical and/or logical relationships between building elements of a construction project.

In some examples wherein the machine-learning model 420 is trained based on BIM data and/or BIM files, the machine-learning process may include a semi-supervised machine-learning process that includes extracting indications of a plurality of building elements and/or indications of logical relationships between pairs of building elements from labeled BIM data and/or datums within a BIM file. To that end, such a semi-supervised process may include extracting previously notated relationship data within a BIM file and/or may include extracting relationship data based on tagged or autonomously notated data from BIM software, from which the BIM file was generated.

In some examples, training the machine learning model 420 may include performing a transfer learning process on the training data. Via a transfer learning process, the machine-learning model 420 may detect logical relationships between certain building elements of the training data and use these detected relationships to adapt these learnings for other or similar building elements. For example, such a transfer learning process may identify or detect a control-based logical relationship (e.g., a “master-slave” relationship) between two building units, wherein a controlling unit (e.g., a thermostat controller) controls another building element (e.g., an HVAC system); then, the machine-learning model, based on these learnings, can infer that similar logical relationships, in processed input data, between similar building elements should exist. This type of transfer learning can predict the presence of such logical relationships in both BIM data and from non-BIM documents.

Having received the construction project data 405 for a given construction project, the method 400 may further include receiving a request to generate a building elements graph based on the construction project data 405, as illustrated in block 412. The request for generating the building elements graph may be, for example, provided to the computing platform 200 via a client device, such as an end-user device 300. Additionally or alternatively, the request for generating the building elements graph may be provided via one or more application program interfaces (APIs) of, or associated with, the computing platform 200. An “API,” as defined herein, refers to an interface for one or more computer programs to communicate with one another, which offers some service or functionality to the other program(s).

The method 400 further includes providing the construction project data 405 to the machine-learning model 420, as input to the machine-learning model 420, as illustrated in block 414. To that end, the machine-learning model 420 is configured to receive, as input, construction project data, which, for example, may include receiving the construction project data 405 as input, as illustrated in block 422. Based on the received construction project data (e.g., the construction project data 405) and in view of the training dataset 403, the machine learning model 420 may further be configured to identify a plurality of building elements associated with the input construction project data, as illustrated in block 424. Then, based on an evaluation of the one or more building elements associated with the input construction project, in view of the training data set, the machine-learning model 420 may further be configured to determine a set of respective physical relationships between pairs of building elements associated with the input construction project and determine a set of respective logical relationships between pairs of building elements associated with the input construction project, as illustrated in block 426. Further still, based on the determined building elements, the determined set of respective physical relationships, and the determined set of respective logical relationships, the machine-learning model 420 may be further configured to generate and/or output a building elements graph 409 for the input construction project, as illustrated in block 428.

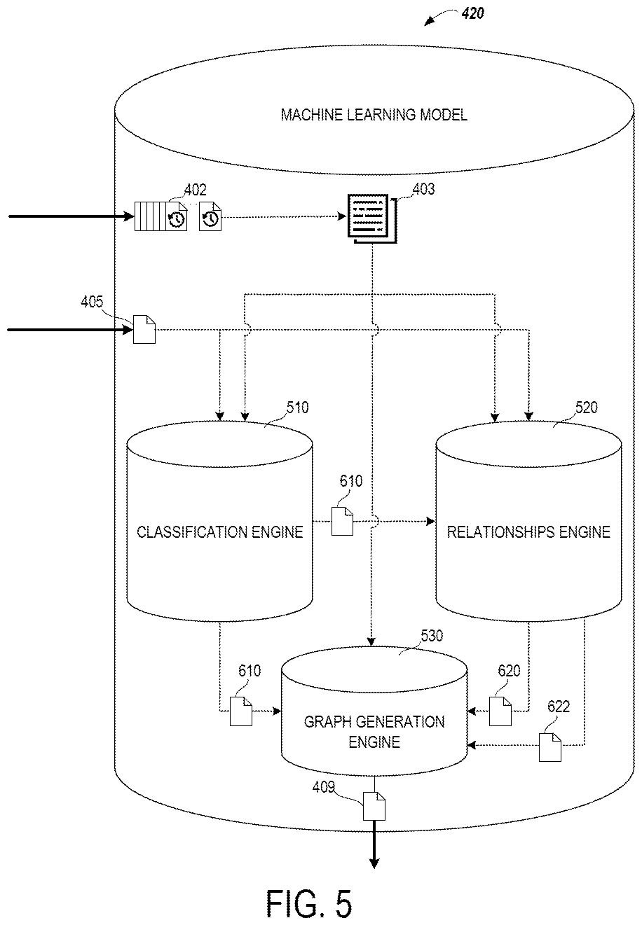

Turning now to FIG. 5 and with continued reference to FIG. 4, an example graphic diagram for an implementation of the machine-learning model 420 is illustrated, which may include example components of the machine-learning model 420 and/or example data throughput of, or associated with, the machine learning model 420. In some examples, the machine-learning model may utilize the training data 403 to determine and/or enhance a previously determined classification engine 510, which may be utilized in determining and/or identifying a plurality of building elements 610 of a construction project, based on the input construction project data 405. In such examples, the classification engine 510 may be configured for extracting and/or classifying the plurality of building elements 610 associated with the input construction project, which may be a given construction project of the method 400 of FIG. 4. To that end, the classification engine 510 may receive, as input, construction project data 405 and output a plurality of building elements 610 associated with the input construction project.

In some additional or alternative examples, the machine-learning model 420 may include a relationships engine 520. The relationships engine 520 may be configured to determine relationships between input building elements and may be based on the training data 403. To that end, the machine-learning model 420 may be configured to generate the relationships engine 520 based on the indications of a plurality of building elements and the indications of respective logical relationships between pairs of building elements in the plurality of building elements, that are present in the training data 403. Then, the relationships engine 520 may be utilized by the machine-learning model 420 to determine relationships between pairs of building elements associated with the input construction project. In some examples, the relationships engine 520 may receive, as input, the plurality of building elements 610 output by the classification engine 510. In such examples, the relationships engine 520 may evaluate the input plurality of building elements 610 and/or the input construction project data 405, in view of the training data 403, and output one or more of a plurality of physical relationships 620 (each between two or more of the plurality of building elements 610), a plurality of logical relationships 622 (each between two or more of the building elements 610), or combinations thereof.

Further still, the machine-learning model 420 may include a graph generation engine 530, which is configured to generate the building elements graph 409 based on an evaluation of one or more of the input construction project data 405, the plurality of building elements 610, the plurality of physical relationships 620, the plurality of logical relationships 622, or combinations thereof, in view of the training dataset 403. The graph generation engine 530 may generate, compile, derive, and/or otherwise determine the building elements graph 409 based on any construction-based data input to the machine-learning model 420 and/or any other predicted or determined data generated by the machine-learning model 420. The resultant building elements graph 409 may be a data structure and/or data object that includes indications of the plurality of building elements 610 and any logical and/or physical relationships 620, 622 therebetween.

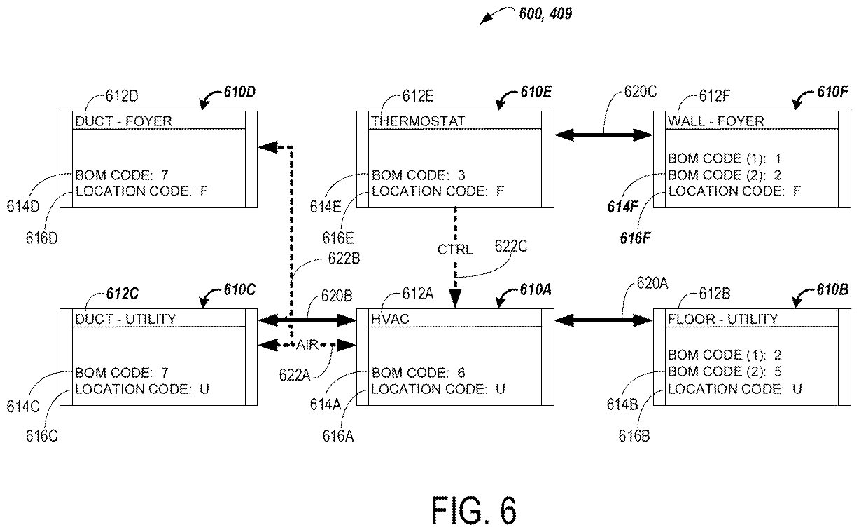

As one such non-limiting example of a data structure for a building elements graph, FIG. 6 illustrates a block diagram of an example data structure 600 that may form part of the building elements graph 409, which includes examples for the plurality of building elements 610, examples for the plurality of physical relationships 620, and examples for the plurality of logical relationships 622. To that end, each block representing a given building element 610A-610F may include, but are not limited to, an identifying indication 612, a BOM code indication 614, and/or a location code indication 616. The identifying indication 612 may be data indicative of a name or specific-identifying information associated with a given building element 610 (e.g., “HVAC,” “floor-utility,” “duct-utility,” “duct-foyer,” “wall-foyer,” “thermostat,” etc.).

The BOM code(s) 614 may include information that indicates a cost or an item type associated with the given building element; accordingly, building elements, when of a similar type or style, may share a BOM code, indicating a similar cost or type of element (e.g., both building elements 610C, 610D include a BOM code 614C, 614D of “7,” which may be indicative of a duct, pursuant to respective identifying indications 612C, 612D (“duct-utility” and “duct-foyer,” respectively)). Further still, a given building element may be a composite building element that includes multiple components or materials in a bill of materials and, accordingly, may be associated with two or more BOM codes (e.g., the BOM code 614B includes data of BOM Codes “2” and “5,” which may be indicative of different components in a BOM that are associated with the floor in the utility room).

Further, the building elements 610, as represented in the data structure of the building elements graph 600, may include the location indication 616, which is an identifier of a location of the construction project in which a given building element 600 resides. For example, each of the building elements 610A, 610B, 610C have a location indication 616A, 616B, 616C of “U,” which may indicate that each of the building elements 610A, 610B, 610C reside within or are associated with a utility room location of a building associated with the building elements graph 409. Similarly, each of the building elements 610D, 610E, 610F have a location indication 616D, 616E, 616F of “F,” which may indicate that each of the building elements 610D, 610E, 610F reside within or are associated with a foyer location of the building associated with the building elements graph 409.

The indications of the plurality of physical relationships 620 are each illustrated with solid lines connecting individual building elements 610, whereas indications of the plurality of logical relationships are each illustrated with dotted lines. For example, the plurality of physical relationships 620 include a first physical relationship 620A between the building elements 610A, 610B (e.g., the HVAC building element 610A is positioned atop the utility room floor building element 610B), a second physical relationship 620B between the building elements 610A, 610C (e.g., the HVAC building element 610A resides in the same utility room as the utility room duct building element 610C), and a third physical relationship 620C between the building elements 610E, 610F (e.g., a thermostat building element 610E is affixed to or otherwise attached to a foyer wall building element 610F).

As illustrated, the indications of the logical relationships 622 may exist between building elements independent of whether a physical relationship also exists between such elements. For example, first and second logical relationships 622A, 622B indicate logical relationships associated with airflow and/or other HVAC-based functionality. To that end, the first logical relationship 622A is indicative of airflow between (to and/or from) the HVAC building element 610A and the utility room duct building element 610C. Incidentally, these two building elements also share a physical relationship 620B. The second logical relationship 622B is indicative of airflow between (to/from) the HVAC building element 610A and a foyer duct building element 610D. These two building elements, on the other hand, do not have a corresponding physical relationship. A third logical relationship 622C is indicative of a control-based logical relationship between the HVAC building element 610A and the thermostat building element 610E. The third logical relationship 622C may indicate that the thermostat building element 610E provides control instructions to the HVAC building element 610A, that the HVAC building element 610A provides data to the thermostat building element 610E, among other data-based or communication-based relationships between the HVAC building element 610A and the thermostat building element 610E.

Accordingly, the data structure 600 for the building elements graph 409 may beneficially include an identification of building elements 610 and the relationships 620, 622 therebetween. Further, the example shown in FIG. 6 may represent only a small fraction of the total number of building elements that might be present on a construction project, and thus a similar building elements graph for an entire project may include substantially more data. As discussed above, the data of the building elements graph 409 and/or the relationships 620, 622 revealed therein may have wide use both during and after construction.

Returning now to FIG. 4, as discussed above, the method 400 may identify a plurality of building elements associated with a given construction project, the plurality of building elements including, at least, a first building element and a second building element. Further still, based on inputting the construction project data 405 as the input construction project data of the machine-learning model 420, the method 400 may determine a given set of physical relationships between pairs of the building elements associated with the given construction project and a given set of respective logical relationships between pairs of the building elements associated with the given construction project. The given set of respective logical relationships may comprise a logical relationship between the first building element and the second building element.

In some examples, the given set of physical relationships includes a physical relationship between the first building element and the second building element, in addition to the logical relationship. Alternatively, in other examples, the given set of physical relationships may not include a physical relationship between the first building element and the second building element and, rather, there is only a logical relationship between the first building element and the second building element.

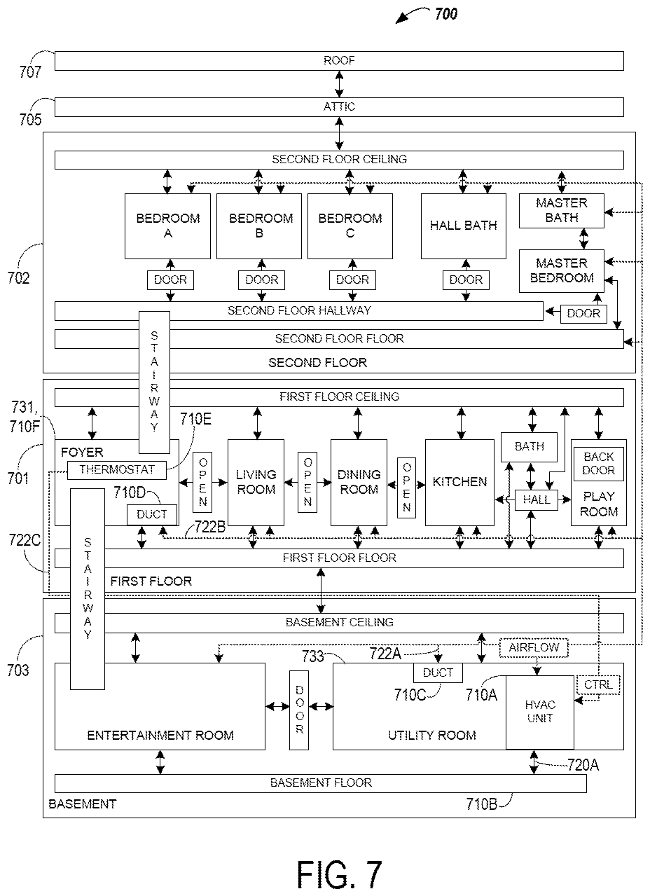

Having determined the building elements graph 409, via use of the machine-learning model 420, the method 400 may further include storing the building elements graph 409 on at least one machine-readable medium of or associated with the computing platform 200 and/or an end-user device 300, as illustrated in block 416. Additionally or alternatively, in some examples, the method 400 may further include causing a client device to present a visual representation of the building elements graph 409, as illustrated in block 418. One possible example of such visual representation of the building elements graph 409 is shown in FIG. 6. Another example of such a visual representation 700, indicative of at least some of the building elements graph 409 and/or the data structure 600 thereof, is illustrated in FIG. 7.

As illustrated, the visual representation 700 may take the form of the location-based icon-graph shown in FIG. 7. However, a visual representation of a building elements graph need not be of the form of the visual representation 700 and may comprise any other representation that can be presented to a user of the end-user device 300, such as, but not limited to, a visual representation of a data structure (e.g., the depiction of the data structure 600 of FIG. 6), a two-dimensional map of a construction project, a 3-D map of a construction project, a virtual reality (VR) or augmented reality (AR) depiction of a construction project, and/or any other visual representation indicative of building elements and relationships therebetween.

The example visual representation 700 includes indications of a plurality of locations in the building, which include, but are not limited to including, a first floor indication 701, a second floor indication 702, a basement indication 703, an attic indication 705, a roof indication 707, a foyer indication 731, and a utility room indication 733. As illustrated, the visual representation may include a plurality of visual building element indicators 710, each associated with one of the building elements. To that end, the visual representation 700 may include visual building element indicators 710A, 710B, 710C, 710D, 710E, 710F, each being, respectively, associated with and/or based on building elements 610A, 610B, 610C, 610D, 610E, 610F.

Similarly, physical relationships between building elements 610, represented in their visual form by the visual building element indications discussed above, may be represented by visual physical relationship indicators (e.g., the arrowed line 720A indicating the physical relationship between the HVAC building element 610A and the utility room floor building element 610B), which may be represented as solid lines. As another possibility, physical relationships may be inferred by proximity of visual building element indicators 710 with respect to one another (e.g., the stairway has a physical relationship with the first floor as indicated by visually overlapping of their icons, the HVAC unit has a physical relationship with the utility room floor as it is visually depicted on top of the floor, etc.).

Lastly, the visual representation 700 may include a plurality of visual logical relationship indicators 722, each of which is based on and/or associated with one of the logical relationships 622 shown in FIG. 6. To that end, the visual representation 700 may include visual logical relationship indicators 722A, 722B, 722C, each being, respectively, associated with and/or based on logical relationships 622A, 622B, 622C. To that end, visual logical relationship indicators 722A, 722B are indicative of the airflow-based logical relationships between the HVAC building element 610A and, respectively, the utility room duct building element 610C and the foyer duct building element 610D. Further, the visual logical relationship indicator 722C is indicative of the control based logical relationship 622C between the HVAC building element 610A and the thermostat building element 610E.

The information contained in the example data structure 600 and/or the example visual representation 700 is merely for the purposes of explanation and example and is intended to be non-limiting. To that end, the data structure 600, the visual representation 700, and/or the building elements graph 409 may include additional information or less information than that discussed herein. To that end, particularly with respect to the visual representation 700, hierarchically organized data may be accessed via user input and/or user interaction with the visual representation 700 (e.g., clicking or touching a building element indication 710 expands on details of said element, user input zooms in or zooms out on locations and/or building elements of the visual representation 700, user input edits data associated with a building element 610 or indication 710 thereof, etc.).

ii. Generating Building Information Summaries, Based on Building Elements Graphs

While discussed as a visual representation of the building elements graph 409, it is certainly contemplated that the visual representation 700 may be utilized as a building information summary that is used either during or after the execution phase of a construction project. In this regard, the computing platform 200 may generate a building information summary, such as the example representation shown in FIG. 7) based on a building elements graph that was generated as output of the method 400, as discussed above. For example, the computing platform 200 may receive a request, e.g., from an end-user device 300, to generate a building information summary and may generate said building information summary based on an input building elements graph.

### IV. Conclusion

Example embodiments of the disclosed innovations have been described above. Those skilled in the art will understand, however, that changes and modifications may be made to the embodiments described without departing from the true scope and spirit of the present invention, which will be defined by the claims.

While the foregoing is described in the context of data objects related to construction projects, it should be understood that the disclosed technology may be utilized in connection with other kinds of data objects as well. For example, the disclosed technology may be utilized for automatically generating content for data objects associated with professional or business tasks and projects, data objects associated with academic tasks and projects, data objects associated with legal tasks and projects, data objects associated with interpersonal or social tasks or projects, and the like.

For instance, those in the art will understand that the disclosed operations for training and utilizing machine-learning models and/or LLMs in the manner described herein to generate elements graphs, may not be limited to only construction projects. Rather, the disclosed operations could be used in other contexts in connection with other types of projects as well.

Further, to the extent that examples described herein involve operations performed or initiated by actors, such as “humans,” “operators,” “users,” or other entities, this is for purposes of example and explanation only. The claims should not be construed as requiring action by such actors unless explicitly recited in the claim language.

1. A computing platform comprising:
at least one network interface;
at least one processor;
at least one non-transitory computer-readable medium; and
program instructions stored on the at least one non-transitory computer-readable medium that are executable by the at least one processor such that the computing platform is configured to:
train at least one machine-learning model by carrying out a machine-learning process on a training data set that includes a plurality of construction-based data objects, the plurality of construction-based data objects including (i) indications of a plurality of building elements, (ii) indications of respective logical relationships between pairs of building elements in the plurality of building elements, wherein the at least one machine-learning model is configured to (i) receive, as input, construction project data associated with an input construction project, (ii) based on the received construction project data, identify a plurality of building elements associated with the input construction project, (iii) based on an evaluation of the one or more building elements associated with the input construction project, in view of the training data set, determine a set of respective physical relationships between pairs of building elements associated with the input construction project and a set of respective logical relationships between pairs of building elements associated with the input construction project, and (iv) based on the determined set of respective physical relationships and the determined set of respective logical relationships, generate a building elements graph for the input construction project;
receive construction project data associated with a given construction project;
receive a request to generate a building elements graph for the given construction project;
input the construction project data associated with the given construction project into the machine-learning model and thereby:
identifying a plurality of building elements associated with the given construction project, the plurality of building elements including a first building element and a second building element,
determining a given set of respective physical relationships between pairs of the building elements associated with the given construction project and a given set of respective logical relationships between pairs of the building elements associated with the given construction project, the given set of respective logical relationships comprising a logical relationship between the first building element and the second building element, and
based on the given set of respective physical relationships and the given set of respective logical relationships, generating a building elements graph for the given construction project; and
store the building elements graph for the given construction project on the at least one non-transitory computer-readable medium.

2. The computing platform of claim 1, the given set of physical relationships includes a physical relationship between the first building element and the second building element.

3. The computing platform of claim 1, wherein the given set of physical relationships does not include a physical relationship between the first building element and the second building element.

4. The computing platform of claim 1, further comprising program instructions stored on the at least one non-transitory computer-readable medium that are executable by the at least one processor such that the computing platform is configured to cause a client device to present a visual interface, the visual interface usable for viewing an indication of the building elements graph.

5. The computing platform of claim 1, wherein the construction project data includes one or more of a specification for the given construction project, drawings for the given construction project, a bill of materials (BOM) for the given construction project, user input associated with the given construction project, a location hierarchy for the given construction project, a data sheet for a property element of the given construction project, a cost code, or combinations thereof.

6. The computing platform of claim 5, wherein the construction project data includes building information modelling (BIM) data.

7. The computing platform of claim 1, wherein the machine-learning model is further configured to generate a classification engine, based on the training data set, for extracting and classifying the plurality of building elements associated with the given construction project.

8. The computing platform of claim 7, wherein identifying the plurality of building elements associated with the input construction project includes identifying, by a relationships engine of the machine-learning model, the extracted and classified plurality of building elements.

9. The computing platform of claim 1, wherein the machine-learning model is further configured to generate a relationships engine, based on the indications of a plurality of building elements and the indications of respective logical relationships between pairs of building elements in the plurality of building elements, the relationships engine for determining relationships between pairs of building elements associated with the input construction project.

10. The computing platform of claim 1, wherein the training data set includes BIM data associated with one or more construction projects.

11. The computing platform of claim 10, wherein the machine-learning process comprises a semi-supervised machine-learning process that includes extracting the indications of a plurality of building elements and the indications of respective logical relationships between pairs of building elements from labelled BIM datums in the BIM data.

12. The computing platform of claim 1, further comprising program instructions stored on the at least one non-transitory computer-readable medium that are executable by the at least one processor such that the computing platform is configured to cause a client device to:
receive a request to generate a building information summary; and
generate a building information summary based on the building elements graph.

13. The computing platform of claim 12, further comprising program instructions stored on the at least one non-transitory computer-readable medium that are executable by the at least one processor such that the computing platform is configured to cause a client device to:
train a large language model (LLM) by carrying out a LLM machine-learning process on a second training data set that includes construction-based data, the LLM configured to (i) receive, as input, an LLM input building elements graph, and (ii) based on an evaluation of the LLM input building elements graph, in view of the second training dataset, determine an output building information summary;
input the building elements graph to the LLM, as the LLM input building elements graph; and
receive a given output building information summary for the given construction project, as output from the LLM, and
wherein generating the building information summary is further based on the given output building information summary.

14. At least one non-transitory computer-readable medium, wherein the at least one non-transitory computer-readable medium is provisioned with program instructions that, when executed by at least one processor, cause a computing platform to:
train at least one machine-learning model by carrying out a machine-learning process on a training data set that includes a plurality of construction-based data objects, the plurality of construction-based data objects including (i) indications of a plurality of building elements, (ii) indications of respective logical relationships between pairs of building elements in the plurality of building elements, wherein the at least one machine-learning model is configured to (i) receive, as input, construction project data associated with an input construction project, (ii) based on the received construction project data, identify a plurality of building elements associated with the input construction project, (iii) based on an evaluation of the one or more building elements associated with the input construction project, in view of the training data set, determine a set of respective physical relationships between pairs of building elements associated with the input construction project and a set of respective logical relationships between pairs of building elements associated with the input construction project, and (iv) based on the determined set of respective physical relationships and the determined set of respective logical relationships, generate a building elements graph for the input construction project;
receive construction project data associated with a given construction project;
receive a request to generate a building elements graph for the given construction project;
input the construction project data associated with the given construction project into the machine-learning model and thereby:
identifying a plurality of building elements associated with the given construction project, the plurality of building elements including a first building element and a second building element,
determining a given set of respective physical relationships between pairs of the building elements associated with the given construction project and a given set of respective logical relationships between pairs of the building elements associated with the given construction project, the given set of respective logical relationships comprising a logical relationship between the first building element and the second building element, and
based on the given set of respective physical relationships and the given set of respective logical relationships, generating a building elements graph for the given construction project; and
store the building elements graph for the given construction project on at least one machine-readable medium associated with the computing platform.

15. The at least one non-transitory computer-readable medium of claim 14, wherein the machine-learning model is further configured to generate a classification engine, based on the training data set, for extracting and classifying the plurality of building elements associated with the given construction project.

16. The at least one non-transitory computer-readable medium of claim 14, wherein the machine-learning model is further configured to generate a relationships engine, based on the indications of a plurality of building elements and the indications of respective logical relationships between pairs of building elements in the plurality of building elements, the relationships engine for determining relationships between pairs of building elements associated with the input construction project.

17. The at least one computer-readable medium of claim 14, wherein the training data set includes BIM data associated with one or more construction projects, and
wherein the machine-learning process comprises a semi-supervised machine-learning process that includes extracting the indications of a plurality of building elements and the indications of respective logical relationships between pairs of building elements from labelled BIM datums in the BIM data.

18. A method carried out by a computing platform, the method comprising:
training at least one machine-learning model by carrying out a machine-learning process on a training data set that includes a plurality of construction-based data objects, the plurality of construction-based data objects including (i) indications of a plurality of building elements, (ii) indications of respective logical relationships between pairs of building elements in the plurality of building elements, wherein the at least one machine-learning model is configured to (i) receive, as input, construction project data associated with an input construction project, (ii) based on the received construction project data, identify a plurality of building elements associated with the input construction project, (iii) based on an evaluation of the one or more building elements associated with the input construction project, in view of the training data set, determine a set of respective physical relationships between pairs of building elements associated with the input construction project and a set of respective logical relationships between pairs of building elements associated with the input construction project, and (iv) based on the determined set of respective physical relationships and the determined set of respective logical relationships, generate a building elements graph for the input construction project;
receiving construction project data associated with a given construction project;
receiving a request to generate a building elements graph for the given construction project;
inputting the construction project data associated with the given construction project into the machine-learning model and thereby:
identifying a plurality of building elements associated with the given construction project, the plurality of building elements including a first building element and a second building element,
determining a given set of respective physical relationships between pairs of the building elements associated with the given construction project and a given set of respective logical relationships between pairs of the building elements associated with the given construction project, the given set of respective logical relationships comprising a logical relationship between the first building element and the second building element, and
based on the given set of respective physical relationships and the given set of respective logical relationships, generating a building elements graph for the given construction project; and
storing the building elements graph for the given construction project on at least one machine-readable medium associated with the computing platform.

19. The method of claim 18, further comprising causing a client device to present a visual interface, the visual interface usable for viewing an indication of the building elements graph.

20. The method of claim 18, further comprising receiving a request to generate a building information summary; and
generating a building information summary based on the building elements graph.
